(19) United States
(12) Patent Application Publication
(10) Pub. No.: US 2012/0255770 A1
(43) Pub. Date: Oct. 11, 2012

(54) Carrier and Method for Fabricating Thereof

(76) Inventors: Han-Pei Huang, Taoyuan City (TW); Yu-Ying Chao, Taoyuan City (TW); Chih-Hsueh Shih, Taoyuan City (TW)

(21) Appl. No.: 13/370,360

(22) Filed: Feb. 10, 2012

(30) Foreign Application Priority Data
Apr. 8, 2011 (TW) 100112239

(51) Int. Cl. H05K 1/11; B32B 37/14; B32B 37/10

(52) U.S. Cl. 174/266; 156/280; 156/272.8

(57) ABSTRACT

A method for fabricating a carrier is disclosed, wherein the carrier is applied for a microelectromechanical sensing device. The method includes the steps of: providing a first substrate, wherein the first substrate includes a first metal layer, a first dielectric layer, and a first opening; providing a second substrate, wherein the second substrate includes a second metal layer, a second dielectric layer, and a second opening; providing a reticular element; pressing the first substrate, the reticular element, and the second substrate to form a composite substrate, wherein the first opening and the second opening form a hole, and the reticular element is positioned in the hole; and forming at least one conductive via in the composite substrate.

### BACKGROUND OF THE INVENTION

1. Field of the Invention

The present invention relates to a method for fabricating a carrier; more particularly, the present invention relates to a method for fabricating a carrier applied for a microelectromechanical sensing device.

2. Description of the Related Art

The general atmospheric pressure or acoustic sensing products of microelectromechanical systems (such as a microelectromechanical microphone, or a microelectromechanical pressure sensor) must leave an opening after packaging, allowing acoustics or a change of atmospheric pressure to be detected; however, the opening allows entry of dust or saliva generated by a user, which could easily pollute the chip inside of the microelectromechanical packaging or the film structure. In the prior art, to solve that problem, a cover with a gate field is applied on the opening; however, the cover must be pasted in a plurality of single micro metal gates one by one, such that the cost of money and time increases, and the production yield may not be guaranteed.

Therefore, there is a need to provide a method for fabricating a carrier to solve the abovementioned problem.

### SUMMARY OF THE INVENTION

It is an object of the present invention to provide a method for fabricating a carrier; the carrier is applied for a microelectromechanical sensing device to prevent a microelectromechanical sensing device with an outward opening to be polluted by an external pollutant.

To achieve the abovementioned object, the present invention provides a method for fabricating a carrier, wherein the carrier is applied for a microelectromechanical sensing device. The method for fabricating a carrier includes the steps of: providing a first substrate, wherein the first substrate includes a first metal layer, a first dielectric layer, and a first opening, wherein the first metal layer is positioned above the first dielectric layer, and the first opening runs through the first metal layer and the first dielectric layer; providing a second substrate, wherein the second substrate includes a second metal layer, a second dielectric layer, and a second opening, wherein the second dielectric layer is positioned above the second metal layer, the second opening runs through the second metal layer and the second dielectric layer, and a position and an area of the first opening correspond to the position and the area of the second opening; providing a reticular element; pressing the first substrate, the reticular element, and the second substrate to form a composite substrate, wherein the first opening and the second opening form a hole, and the reticular element is positioned in the hole; and forming at least one conductive via in the composite substrate.

In one embodiment of the present invention, after the step of forming at least one conductive via in the composite substrate, the method further comprises the step of patterning the first metal layer and the second metal layer to form a first circuit layer and a second circuit layer.

To achieve the abovementioned object, the present invention further provides a method for fabricating a carrier, wherein the carrier is applied for a microelectromechanical sensing device, the method for fabricating a carrier includes the steps of: providing a first substrate, wherein the first substrate comprises a first metal layer and a first dielectric layer, wherein the first metal layer is positioned above the first dielectric layer; providing a second substrate, wherein the second substrate includes a second metal layer and a second dielectric layer, wherein the second dielectric layer is positioned above the second metal layer; providing a reticular element, wherein the reticular element is made of metal or ceramics; pressing the first substrate, the reticular element, and the second substrate to form a composite substrate; forming a hole on the composite substrate via laser ablation, wherein a part of the reticular element is exposed via the hole; and forming at least one conductive via in the composite substrate.

In one embodiment of the present invention, after the step of forming at least one conductive via in the composite substrate, the method further comprises the step: patterning the first metal layer and the second metal layer to form a first circuit layer and a second circuit layer.

To achieve the abovementioned object, the present invention further provides a method for fabricating a carrier, wherein the carrier is applied for a microelectromechanical sensing device. The method for fabricating a carrier includes the steps of: providing a first metal layer, a first dielectric layer, a second metal layer, and a second dielectric layer, wherein the first metal layer and the first dielectric layer respectively comprise a first opening which is corresponded, the second metal layer and the second dielectric layer respectively comprise a second opening which is corresponded, and an area and a position of the first opening correspond to the area and the position of the second opening; providing a reticular element, wherein the reticular element is made of metal or ceramics; superposing the first metal layer, the first dielectric layer, the reticular element, the second dielectric layer, and the second metal layer in sequence to form a pressing volume; pressing the pressing volume to form a composite substrate, wherein the first opening and the second opening form a hole, such that the reticular element is positioned in the hole; and forming at least one conductive via in the composite substrate.

In one embodiment of the present invention, after the step of forming at least one conductive via in the composite substrate, the method further comprises the step of patterning the first metal layer and the second metal layer to form a first circuit layer and a second circuit layer.

To achieve the abovementioned object, the present invention further provides a method for fabricating a carrier. The method for fabricating a carrier includes the steps of: providing a first metal layer, a first dielectric layer, a second metal layer, and a second dielectric layer; providing a reticular element, wherein the reticular element is made of metal or ceramics; superposing the first metal layer, the first dielectric layer, the reticular element, the second dielectric layer, and the second metal layer in sequence to form a pressing volume; pressing the pressing volume to form a composite substrate; forming a hole on the composite substrate via laser ablation, wherein a part of the reticular element is exposed via the hole; and forming at least one conductive via in the composite substrate.

In one embodiment of the present invention, after the step of forming at least one conductive via in the composite substrate, the method further comprises the step: patterning the first metal layer and the second metal layer to form a first circuit layer and a second circuit layer.

It is another object of the present invention to provide a carrier applied for a microelectromechanical sensing device; the carrier is used for preventing pollution of the microelectromechanical sensing device with an outward opening by an external pollutant.

To achieve the abovementioned object, the present invention provides a carrier. The carrier comprises a dielectric layer, a first circuit layer, a second layer, at least one conductive via, a reticular element, a hole, and a solder mask. The first circuit layer is positioned on one side of the dielectric; the second circuit layer is positioned on the other side of the dielectric; the at least one conductive via, which passes through the dielectric layer, is electrically connected to the first circuit layer and the second circuit layer; the reticular element is positioned in the dielectric layer; the hole passes through the dielectric layer and exposes a part of the reticular element; and the solder mask is coated on the first circuit layer, the second circuit layer, and the at least one conductive via.

In one embodiment of the present invention, the reticular element is made of metal or ceramics.

### BRIEF DESCRIPTION OF THE DRAWINGS

FIG. 1 illustrates a flowchart of the method for fabricating a carrier of one embodiment of the present invention.

FIG. 2 to FIG. 7 illustrate the schematic views of the method for fabricating the carrier of one embodiment of the present invention.

FIG. 8 illustrates a flowchart of the method for fabricating a carrier of another embodiment of the present invention.

FIG. 9 to FIG. 14 illustrate the schematic views of the method for fabricating the carrier of another embodiment of the present invention.

### DETAILED DESCRIPTION OF THE PREFERRED EMBODIMENT

These and other objects and advantages of the present invention will become apparent from the following description of the accompanying drawings, which disclose several embodiments of the present invention. It is to be understood that the drawings are to be used for purposes of illustration only, and not as a definition of the invention.

The schematic drawings of the embodiments of the present invention are all simplified to show the method for fabricating a heat dissipation substrate of the present invention. The elements shown in the schematic drawing are not the actual figure and configuration in implementation; the number, shape, and size of the elements are designed selectively; and the arrangement of the elements can be more complicated.

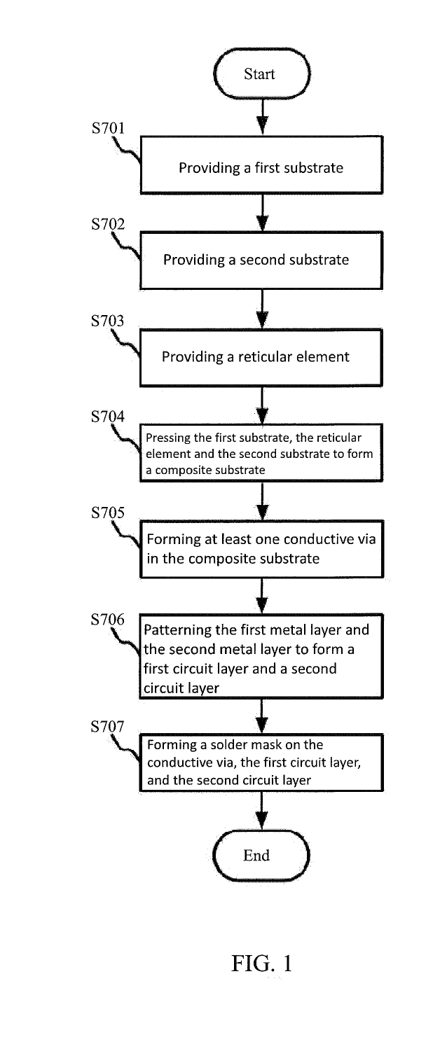

Please refer to FIG. 1, which illustrates a flowchart of the method for fabricating a carrier of one embodiment of the present invention.

The method for fabricating a carrier in one embodiment of the present invention starts at Step S701: providing a first substrate.

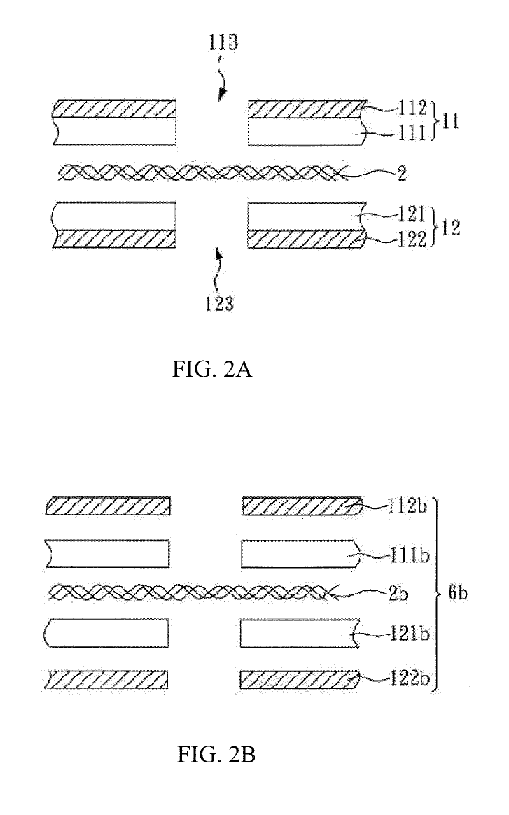

As shown in FIG. 2A, the first substrate 11 comprises a first metal layer 111, a first dielectric layer 112, and a first opening 113; wherein the first metal layer 112 is positioned above the first dielectric layer 111, and the first opening 113 runs through the first metal layer 112 and the first dielectric layer 111.

Then the method goes to Step S702: providing a second substrate.

As shown in FIG. 2A, the second substrate 12 comprises a second metal layer 121, a second dielectric layer 122, and a second opening 123; wherein the second dielectric layer 121 is positioned above the second metal layer 122, the second opening 123 runs through the second metal layer 122 and the second dielectric layer 121, and a position and an area of the first opening 113 correspond to the position and the area of the second opening 123.

In one embodiment of the present invention, the first dielectric layer 111 and the second dielectric layer 121 are made of resin composite material which includes glass fiber (such as a prepreg formed by a glass fiber fabric and an epoxy resin in impregnation), but the present invention is not limited to that design; for example, the first dielectric layer 111 and the second dielectric layer 121 can be made of a resin insulating layer material without any glass fiber fabric (such as RCC, Film-type or Paste).

In one embodiment of the present invention, the first metal layer 112 and the second metal layer 122 are made of copper or a copper alloy, which is pasted on the surface of the first metal layer 112 and the second metal layer 122 in a form of copper foil, but the present invention is not limited to that design.

In one embodiment of the present invention, the first opening 113 and the second opening 123 can by formed in advance via the mechanical drilling process or the laser drilling process, but the present invention is not limited to that design.

Then the method goes to Step S703: providing a reticular element.

As shown in FIG. 2A, in one embodiment of the present invention, the reticular element 2 is made of metal (such as gold, copper, titanium, iron, tin, nickel, aluminum, and at least one material of the composite materials of the alloy), ceramics (such as aluminium oxide or silicon carbide), or another material which will not be damaged in laser ablation. The wavelength of the laser is substantially between 212 nm to 1064 nm, but the present invention is not limited to that design. In one embodiment of the present invention, the reticular element 2 comprises a staggered filamentous structure, and the reticular element 2 can be a planar structure or a solid structure, but the present invention is not limited to that design.

In one embodiment of the present invention, Step S701 can be providing the first metal layer, the first dielectric layer, the second metal layer, and the second dielectric layer. As shown in FIG. 2B, the first metal layer 112b, the first dielectric layer 111b, the second metal layer 122b, and the second dielectric layer 121b are separated; they are not combined as a shape of a composite substrate. It is to be understood that the first metal layer 112b and the first dielectric layer 111b can further respectively comprise a first opening (not assigned a number in the FIG); the second metal layer 122b and the second dielectric layer 121b can further respectively comprise a second opening (not assigned a number in the FIG); the position and area of the first opening and the second opening correspond to each other.

In another embodiment of the present invention, Step S702 can be superposing the first metal layer, the first dielectric layer, the reticular element, the second dielectric layer, and the second metal layer. As shown in FIG. 2B, the first metal layer 112b, the first dielectric layer 111b, the reticular element 2b, the second dielectric layer 121b, and the second metal layer 122b are superposed in sequence, to form a pressing volume 6b.

In another embodiment of the present invention, Step S703 can be providing a reticular element.

Then the method goes to Step S704: pressing the first substrate, the reticular element, and the second substrate to form a composite substrate.

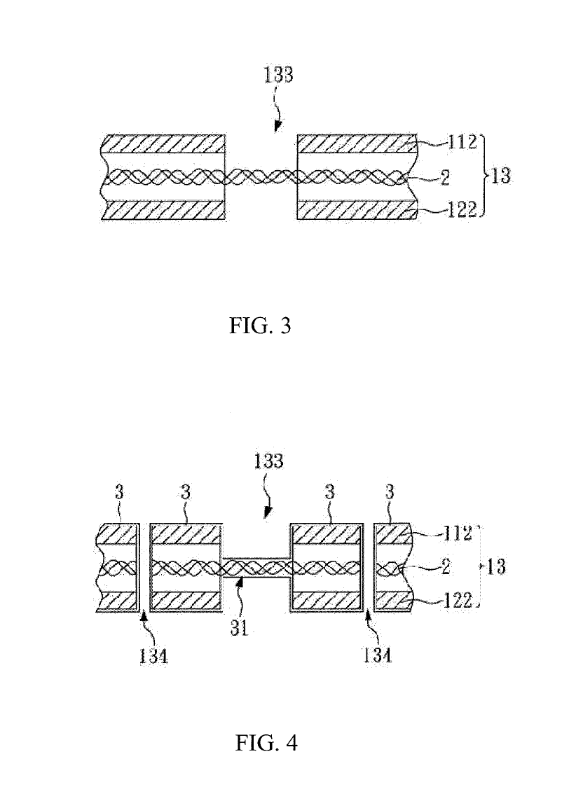

As shown in FIG. 3, Step S704 presses the first substrate 11, the reticular element 2, and the second substrate 12 to form a composite substrate 13; wherein the first opening 113 and the second opening 123 form a hole 133, and the reticular element 2 is positioned in the hole 133. It is to be understood that, in one embodiment of the present invention, the reticular element 2 can be positioned comprehensively, or positioned partly between the first substrate 11 and the second substrate 12 (not shown in FIG).

In another embodiment of the present invention, Step S704 can be pressing the pressing volume to form a composite substrate. The structure of the composite substrate formed by pressing the pressing volume 6b (as shown in FIG. 2B) is the same as that of the composite substrate 13 in FIG. 3, and the following processes are the same as Step S705 to Step S707.

Then the method goes to Step S705: forming at least one conductive via in the composite substrate.

As shown in FIG. 4, the forming method for the conductive via 134 comprises drilling and forming a conductive layer 3. The drilling method can be mechanical drilling, but the present invention is not limited to that design; wherein the mechanical drilling can pass through the reticular element 2; the forming method of forming a conductive layer 3 can be chemical deposition or copper plating, but the present invention is not limited to that design.

It is to be understood that, when the reticular element 2 is made of metal, and forms the conductive layer 3, the plating copper or other metal will also be plated on the reticular element 2 to form a metal film 31; the metal film 31, shown in FIG. 4 only for illustration, is substantially plated inside the reticular element 2, and is not limited to being formed outside the reticular element 2 as a layered structure.

Then the method goes to Step S706: patterning the first metal layer and the second metal layer to form a first circuit layer and a second circuit layer.

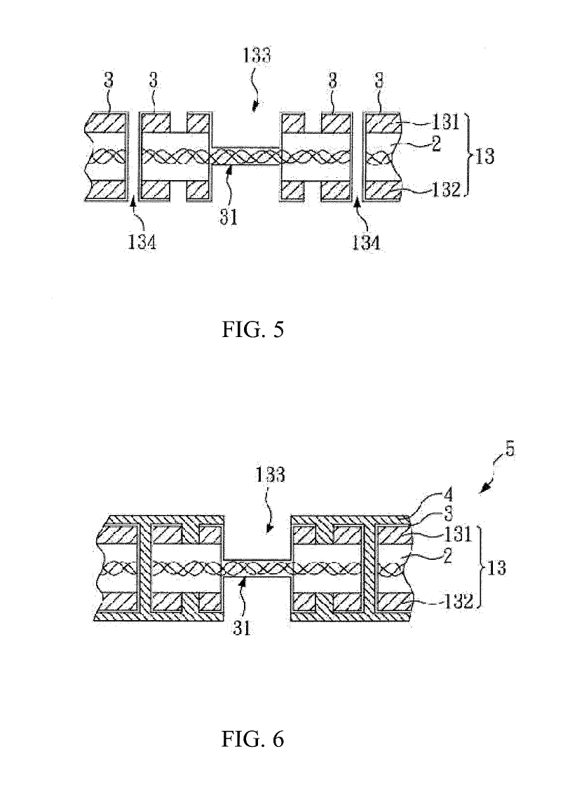

As shown in FIG. 5, Step S706, which executes a patterning process to the composite board 13, patterns the first metal layer 112 and the second metal layer 122 to form a first circuit layer 131 and a second circuit layer 132. The patterning process is already disclosed in a related field, and it is not the feature of the present invention, so there is no need for description here.

Then the method goes to Step S707: forming a solder mask on the conductive via, the first circuit layer, and the second circuit layer.

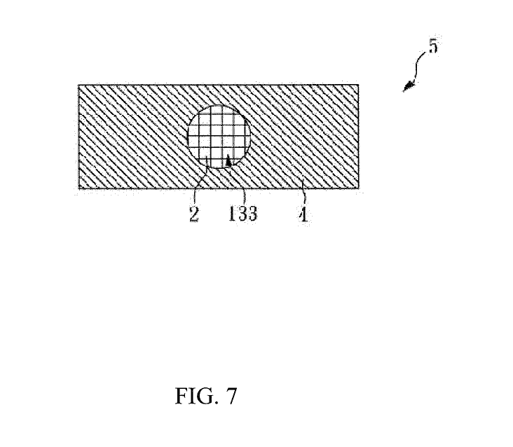

As shown in FIG. 6, Step S707 forms a solder mask 4 on the conductive via 134, the first circuit layer 131, and the second circuit layer 132, to completely form the carrier 5 of the present invention. In one embodiment of the present invention, the method of forming the solder mask can be coating mask, but the present invention is not limited to that design.

FIG. 7 illustrates the top schematic view of the carrier 5 of one embodiment of the present invention. In one embodiment of the present invention, the cover ratio of the reticular element 2 to the hole 113 is substantially between 30% to 70% (the cover ratio is the ratio of the reticular element 2 to a vertical section of the hole 113), but the present invention is not limited to that design. In one embodiment of the present invention, the hole 133 is round, but the present invention is not limited to that shape.

The carrier fabricated by the method for fabricating a carrier of the present invention can be applied to atmospheric pressure or acoustic sensing products of microelectromechanical systems (such as a microelectromechanical microphone, or a microelectromechanical pressure sensor), and provides those features: 1. The reticular element 2 can prevent entry of the external pollution on the outside of the microelectromechanical packaging effectively, to prevent pollution or damage to the sensor element of the microelectromechanical system; 2. The present invention reduces the cost of the cover with a gate field and the loss of the yield, enhancing the production rate; 3. The reticular element 2 comprises a metal film 31 which can prevent external electromagnetic interference.

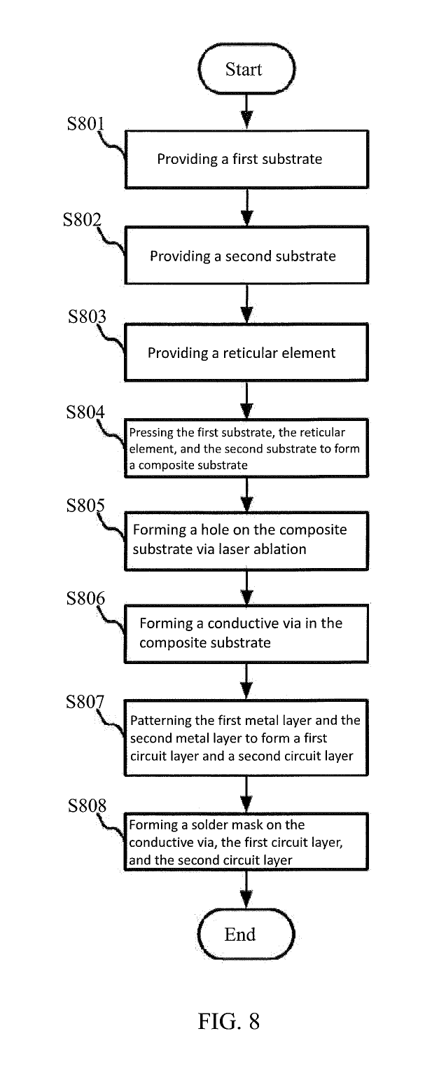

Please refer to FIG. 8, which illustrates a flowchart of the method for fabricating a carrier of another embodiment of the present invention.

The method for fabricating a carrier to another embodiment of the present invention starts at Step S801: providing a first substrate.

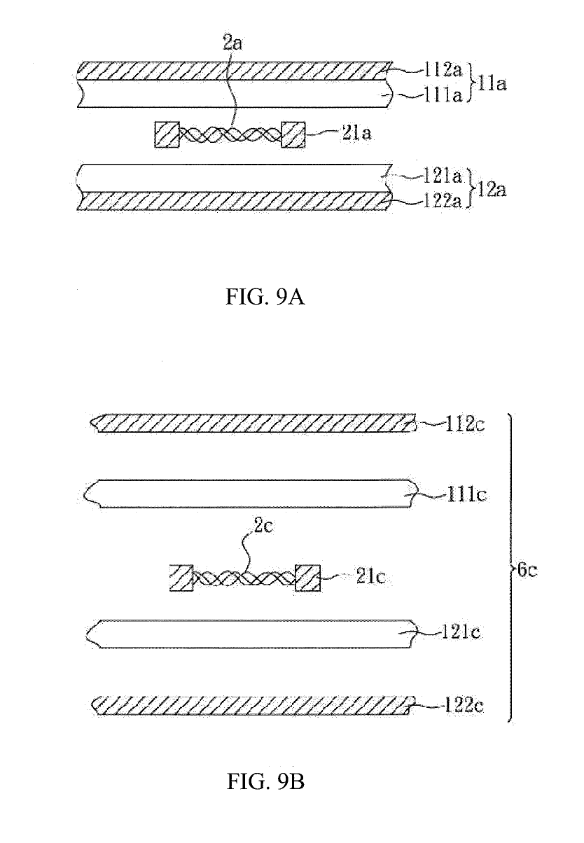

As shown in FIG. 9A, the first substrate 11a comprises a first metal layer 112a and a first dielectric layer 111a, wherein the first metal layer 112a is positioned above the first dielectric layer 111a.

Then the method goes to Step S802: providing a second substrate.

As shown in FIG. 9A, the second substrate 12a includes a second metal layer 122a and a second dielectric layer 121a, wherein the second dielectric layer 121a is positioned above the second metal layer 122a.

Then the method goes to Step S803: providing a reticular element. The description for the first dielectric layer 111a, the second dielectric layer 121a, the second metal layer 122a, the first metal layer 112a, and the reticular element 2a is already disclosed in abovementioned embodiments, so there is no need for description here.

The major difference between the abovementioned embodiment and another embodiment is that the first substrate 11a and the second substrate 12a do not need to form an opening in advance, but a reticular element 2a is positioned partly between the first substrate 11a and the second substrate 12a.

In another embodiment of the present invention, the reticular element 2a comprises a metal frame 21a. The metal frame 21a is made of metal (such as gold, copper, titanium, iron, tin, nickel, aluminum, and at least one material of the composite materials of the alloy), but the present invention is not limited to that design.

In another embodiment of the present invention, Step S801 can be providing the first metal layer, the first dielectric layer, the second metal layer, and the second dielectric layer. As shown in FIG. 9B, the first metal layer 112c, the first dielectric layer 111c, the second metal layer 122c, and the second dielectric layer 121c are separated; they are not combined to form a shape of a composite substrate.

In another embodiment of the present invention, Step S802 can be superposing the first metal layer, the first dielectric layer, the reticular element, the second dielectric layer, and the second metal layer in sequence to form a pressing volume. As shown in FIG. 9B, the first metal layer 112c, the first dielectric layer 111c, the reticular element 2c, the second dielectric layer 121c, and the second metal layer 122c are superposed in sequence to form a pressing volume 6c.

In another embodiment of the present invention, Step S803 can be providing a reticular element. The reticular element 2c comprises a metal frame 21c.

Then the method goes to Step S804: pressing the first substrate, the reticular element, and the second substrate to form a composite substrate.

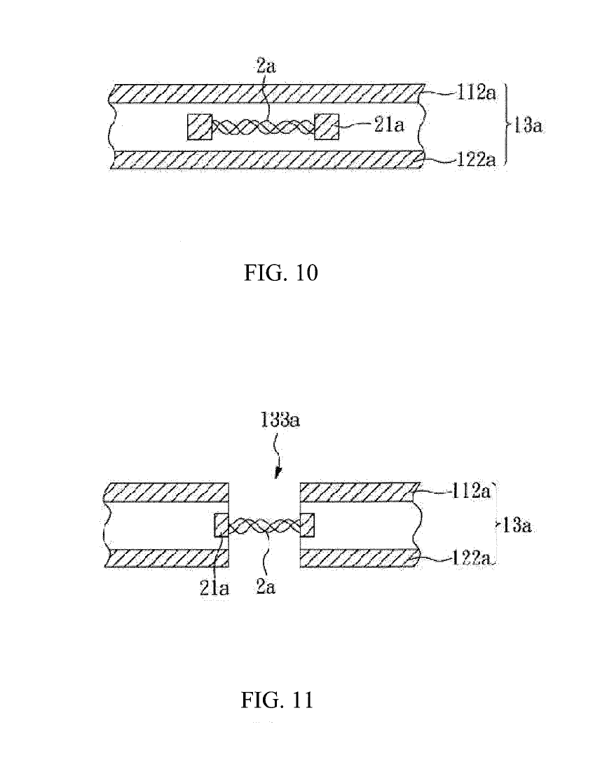

As shown in FIG. 10, in Step S804, the first substrate 11a, the reticular element 2a, and the second substrate 12a are pressed to form a composite substrate 13a.

In another embodiment of the present invention, Step S804 can be pressing the pressing volume to form a composite substrate. The structure of the composite substrate formed by pressing the pressing volume 6c (as shown in FIG. 9B) is the same as that of the composite substrate 13a shown in FIG. 10, and the following processes are the same as Step S805 to Step S808.

Then the method goes to Step S805: forming a hole on the composite substrate via laser ablation.

As shown in FIG. 11, Step S805 forms a hole 133a on the composite substrate 13a via laser ablation; the position of the hole 133a corresponds to the position of the sensor of the microelectromechanical system, and the shape of the metal frame 21a corresponds to the shape and the position of the hole 133a. In another embodiment of the present invention, the area of the reticular element 2a is larger than 5% to 10% of the area of the hole 133a, but the present invention is not limited to that design.

It is to be understood that, when the composite substrate 13a is thick, Step S805 can form the hole via laser ablation from both sides of the composite substrate 13a; the metal frame 21a is used for locating, and preventing damage to the composite substrate 13a which is positioned around the metal frame 21a.

The method goes to Step S806: forming a conductive via in the composite substrate.

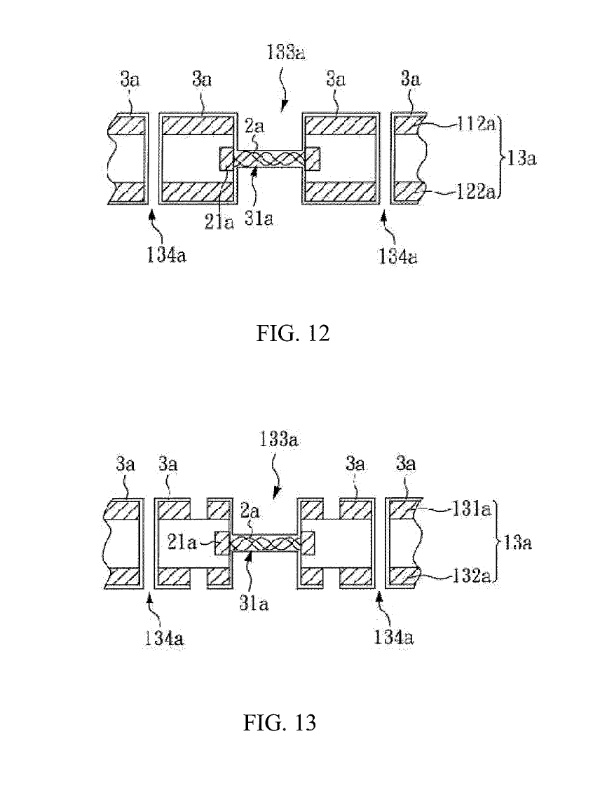

As shown in FIG. 12, in Step S806, a conductive via 134a is formed in the composite substrate 13a. The method of forming the conductive via 134a, the conductive layer 3a, and forming the metal film 31a on the reticular element 2a is already disclosed in an abovementioned embodiment, so there is no need for description here.

The method goes to Step S807: patterning the first metal layer and the second metal layer to form a first circuit layer and a second circuit layer.

As shown in FIG. 13, Step S807, which executes a patterning process to the composite board 13a, patterns the first metal layer 112a and the second metal layer 122a to form a first circuit layer 131a and a second circuit layer 132a.

Then the method goes to Step S808: forming a solder mask on the conductive via, the first circuit layer, and the second circuit layer.

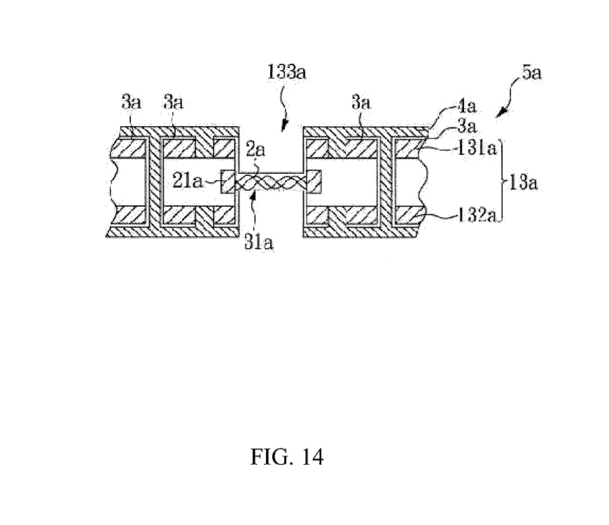

As shown in FIG. 14, Step S808 forms a solder mask 4a on the conductive via 134a, the first circuit layer 131a, and the second circuit layer 132a, such that the carrier 5a of the present invention is completed.

It is noted that the above-mentioned embodiments are only for illustration. It is intended that the present invention cover modifications and variations of this invention provided they fall within the scope of the following claims and their equivalents. Therefore, it will be apparent to those skilled in the art that various modifications and variations can be made to the structure of the present invention without departing from the scope or spirit of the invention.

What is claimed is:

1. A method for fabricating a carrier, wherein the carrier is applied for a microelectromechanical sensing device, the method comprising:
providing a first substrate, wherein the first substrate comprises a first metal layer, a first dielectric layer, and a first opening, wherein the first metal layer is positioned above the first dielectric layer, and the first opening runs through the first metal layer and the first dielectric layer;
providing a second substrate, wherein the second substrate comprises a second metal layer, a second dielectric layer, and a second opening, wherein the second dielectric layer is positioned above the second metal layer, the second opening runs through the second metal layer and the second dielectric layer, and a position and an area of the first opening correspond to a position and an area of the second opening;
providing a reticular element;
pressing the first substrate, the reticular element, and the second substrate to form a composite substrate, wherein the first opening and the second opening form a hole, the reticular element being positioned in the hole; and
forming at least one conductive via in the composite substrate.

2. The method for fabricating the carrier as claimed in claim 1, wherein the step of forming at least one conductive via in the composite substrate further comprises:
patterning the first metal layer and the second metal layer to form a first circuit layer and a second circuit layer.

3. The method for fabricating the carrier as claimed in claim 1, wherein the reticular element is made of metal, and the step of forming at least one conductive via in the composite substrate further comprises:
forming a metal film on the reticular element.

4. A method for fabricating a carrier, wherein the carrier is applied for a microelectromechanical sensing device, the method comprising:
providing a first substrate, wherein the first substrate comprises a first metal layer and a first dielectric layer, wherein the first metal layer is positioned above the first dielectric layer;
providing a second substrate, wherein the second substrate comprises a second metal layer and a second dielectric layer, wherein the second dielectric layer is positioned above the second metal layer;
providing a reticular element, wherein the reticular element is made of metal or ceramics;
pressing the first substrate, the reticular element, and the second substrate to form a composite substrate;
forming a hole on the composite substrate via laser ablation, wherein a part of the reticular element is exposed via the hole; and
forming at least one conductive via in the composite substrate.

5. The method for fabricating the carrier as claimed in claim 4, wherein after the step of forming at least one conductive via in the composite substrate, the method further comprises:
patterning the first metal layer and the second metal layer to form a first circuit layer and a second circuit layer.

6. The method for fabricating the carrier as claimed in claim 4, wherein the reticular element is made of metal, and the step of forming at least one conductive via in the composite substrate further comprises:
forming a metal film on the reticular element.

7. A method for fabricating a carrier, wherein the carrier is applied for a microelectromechanical sensing device, the method comprising:
providing a first metal layer, a first dielectric layer, a second metal layer, and a second dielectric layer, wherein the first metal layer and the first dielectric layer respectively comprise a first opening which is corresponded, the second metal layer and the second dielectric layer respectively comprise a second opening which is corresponded, an area and a position of the first opening correspond to an area and a position of the second opening;
providing a reticular element, wherein the reticular element is made of metal or ceramics;
superposing the first metal layer, the first dielectric layer, the reticular element, the second dielectric layer, and the second metal layer in sequence to form a pressing volume;
pressing the pressing volume to form a composite substrate, wherein the first opening and the second opening form a hole, and the reticular element is positioned in the hole; and
forming at least one conductive via in the composite substrate.

8. The method for fabricating the carrier as claimed in claim 7, wherein after the step of forming at least one conductive via in the composite substrate, the method further comprises:
patterning the first metal layer and the second metal layer to form a first circuit layer and a second circuit layer.

9. The method for fabricating the carrier as claimed in claim 7, wherein the reticular element is made of metal, and the step of forming at least one conductive via in the composite substrate further comprises:
forming a metal film on the reticular element.

10. A method for fabricating a carrier, wherein the carrier is applied for a microelectromechanical sensing device, the method comprising:
providing a first metal layer, a first dielectric layer, a second metal layer, and a second dielectric layer;
providing a reticular element, wherein the reticular element is made of metal or ceramics;
superposing the first metal layer, the first dielectric layer, the reticular element, the second dielectric layer, and the second metal layer in sequence to form a pressing volume;
pressing the pressing volume to form a composite substrate;
forming a hole on the composite substrate via laser ablation, wherein a part of the reticular element is exposed via the hole; and
forming at least one conductive via in the composite substrate.

11. The method for fabricating the carrier as claimed in claim 10, wherein after the step of forming at least one conductive via in the composite substrate, the method further comprises:
patterning the first metal layer and the second metal layer to form a first circuit layer and a second circuit layer.

12. The method for fabricating the carrier as claimed in claim 10, wherein the reticular element is made of metal, and the step of forming at least one conductive via in the composite substrate further comprises:
forming a metal film on the reticular element.

13. A carrier applied for a microelectromechanical sensing device, the carrier comprising:
a dielectric layer;
a first circuit layer positioned on one side of the dielectric;
a second circuit layer positioned on the other side of the dielectric;
at least one conductive via, which passes through the dielectric layer, electrically connected to the first circuit layer and the second circuit layer;
a reticular element positioned in the dielectric layer; and
a hole, which passes through the dielectric layer and exposes a part of the reticular element.

14. The method for fabricating the carrier as claimed in claim 13, wherein the reticular element is made of metal or ceramics.

15. The method for fabricating the carrier as claimed in claim 13, wherein the reticular element comprises a metal frame.

16. The method for fabricating the carrier as claimed in claim 13, wherein the reticular element is coated by a metal film.

17. The method for fabricating the carrier as claimed in claim 14, wherein an area of the reticular element is larger than 5% to 10% of an area of the hole.

18. The method for fabricating the carrier as claimed in claim 13, wherein a cover ratio of the reticular element to the hole is substantially between 30% to 70%.
